(19) United States
(12) Patent Application Publication
(10) Pub. No.: US 2019/0312201 A1
(43) Pub. Date: Oct. 10, 2019

(54) DISPLAY DEVICE MANUFACTURING METHOD

(71) Applicant: Sharp Kabushiki Kaisha, Sakai City, Osaka (JP)

(72) Inventor: Nobuhiro KONDOH, Sakai City (JP)

(21) Appl. No.: 16/469,676

(22) PCT Filed: Sep. 13, 2017
(86) PCT No.: PCT/JP2017/033021

§ 371 Date: Jun. 14, 2019

(51) Int. Cl. H01L 51/00; H01L 51/56

(52) U.S. Cl. CPC H01L 51/003; H01L 51/5253; H01L 51/56; H01L 51/0097

(57) ABSTRACT

Missing parts from which parts of a resin film are cut out are formed in a region between a peeling start position on the resin film and display elements. After the display elements and the missing parts are formed, the resin film is peeled off from the peeling start position mechanically.

### TECHNICAL FIELD

The disclosure is related to a display device manufacturing method.

### BACKGROUND ART

In PTL 1, a method of manufacturing a flexible electronic device is disclosed. The flexible electronic device includes a flexible supporting member, a covering layer for covering a surface of the supporting member, and a circuit formed on the covering layer. The method includes forming a recessed crack-induction pattern, which changes an advancing direction of a crack formed in an end of the covering layer, continuously or intermittently in a region between the end of the covering layer and a circuit formation region to connect the end and the other end of the covering layer.

In PTL 2, there is disclosed a peeling method including a first step, a second step, a third step, and a fourth step. In the first step, a peeling layer containing tungsten is formed on a supporting substrate. In the second step, a peeled layer in which a first layer containing silicon oxynitride and a second layer containing silicon nitride are sequentially laminated, is formed on the peeling layer, and an oxide layer containing tungsten oxide is formed between the peeling layer and the peeled layer. In the third step, by heating treatment, a compound containing tungsten and nitride is generated in the oxide layer. In the fourth step, the peeling layer is peeled off from the peeled layer with the oxide layer as a boundary.

### CITATION LIST

### Patent Literature

PTL 1: WO 2016/204121

PTL 2: JP 2014-187356 A

### SUMMARY

### Technical Problem

In the configurations in PTL 1 and PTL 2, there is a problem in that display elements are damaged at the time of peeling off a resin film from a rigid substrate.

The disclosure has been made to solve the above-mentioned problem, and has an object to peel a resin film without damaging display elements.

### Solution to Problem

In order to achieve the above-mentioned object, according to one aspect of the disclosure, there is provided a display device manufacturing method including, forming a resin film on a rigid substrate, forming a display element on the resin film, forming a missing part, the missing part is missing a part of the resin film, in a first region between a peeling start position on the resin film and the display element, and peeling the resin film mechanically from the peeling start position after the display element and the missing part are formed.

### Advantageous Effects of Disclosure

According to one aspect of the disclosure, an effect of peeling the resin film without damaging the display elements can be obtained.

### BRIEF DESCRIPTION OF DRAWINGS

FIG. 1 is a plan view for illustrating a configuration example of a display device.

FIG. 2A to FIG. 2F are views for illustrating a display device manufacturing method.

FIG. 3 is a view of an intermediate structure in the manufacturing method illustrated in FIG. 2C, which is viewed from a formation surface of a resin film.

FIG. 4 is a plan view for illustrating other arrangement example of missing parts.

FIG. 5 is a plan view for illustrating other arrangement example of the missing parts.

FIG. 6 is a plan view for illustrating other arrangement example of the missing parts.

FIG. 7 is a plan view for illustrating other arrangement example of the missing parts.

FIG. 8 is a plan view for illustrating other arrangement example of the missing parts.

### DESCRIPTION OF EMBODIMENTS

### Configuration of Display Device 1

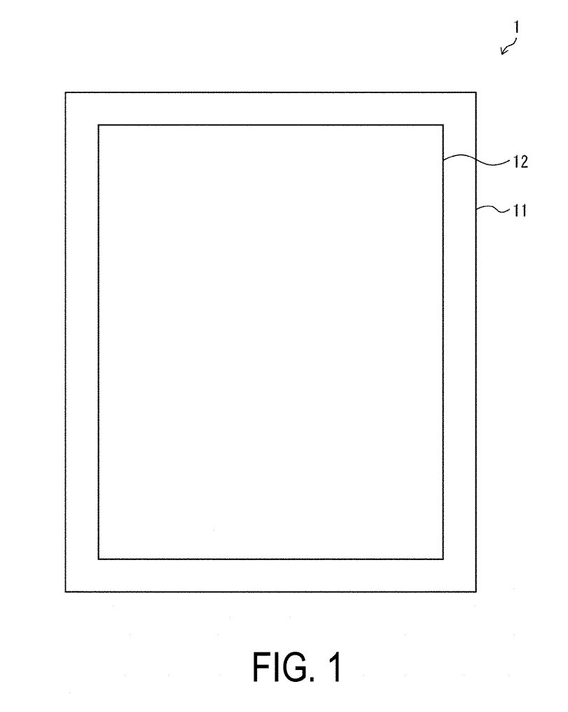

FIG. 1 is a plan view for illustrating a configuration example of a display device 1. The display device 1 is a self-luminous display device, and is formed as, for example, an organic EL luminous device. The display device 1 includes a resin film 11 and a display element 12. The display element 12 is arranged on the resin film 11. The display device 1 further includes a sealing film (not illustrated) configured to seal the display element 12.

The resin film 11 is made of a resin material including polyimide, epoxy, polyamide or the like. The resin film 11 is formed of a resin, and hence is flexible. The display element 12 includes a plurality of light emitting elements (not illustrated), which are self-luminous by being applied with a voltage. The plurality of light emitting elements are formed on the display element 12 in a predetermined plane pattern (for example, a matrix pattern). Each of the light emitting elements is, for example, an organic EL element. Each of the light emitting elements is not limited thereto, and may be an inorganic light emitting element or a quantum dot light emitting element. The sealing film, which performs a thin film encapsulation (TFE) for the display element 12, prevents the respective light emitting elements from being degraded due to moisture or oxygen entering from the outside.

### Peeling Method

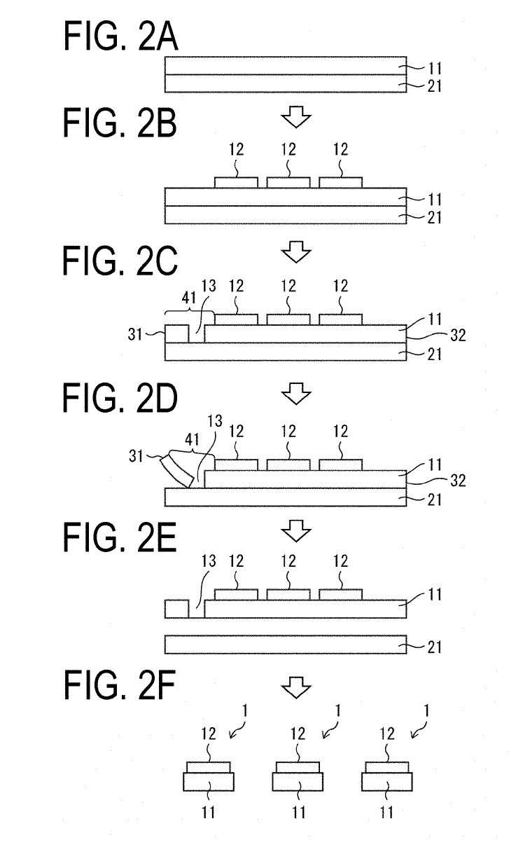

FIG. 2A to FIG. 2F are views for illustrating a method of manufacturing the display device 1. When the manufacturing of the display device 1 is started, the resin film 11 is formed on a rigid substrate 21 (FIG. 2A). The rigid substrate 21 is a substrate formed of a freely selected rigid material, and is, for example, a glass substrate. After the resin film 11 is formed, the display elements 12 are formed on the resin film 11 (FIG. 2B). In this step, at least one display element 12 is formed. In FIG. 2A to FIG. 2F, a plurality of display elements 12 are arranged away from each other.

After the display elements 12 are formed, a missing part 13, missing a part of the resin film 11, is formed in a region 41 (first region) between a peeling start position 31 of the resin film 11 and the display element 12 (FIGS. 2A to 2F). In this step, at least one missing part 13 is formed. In FIG. 2A to FIG. 2F, a plurality of missing parts 13 are formed. The plurality of missing parts 13 are formed simultaneously by a freely selected mechanical method. As an example of such mechanical method, punching of parts of the resin film 11 is exemplified.

### Arrangement Example of Missing Parts 13

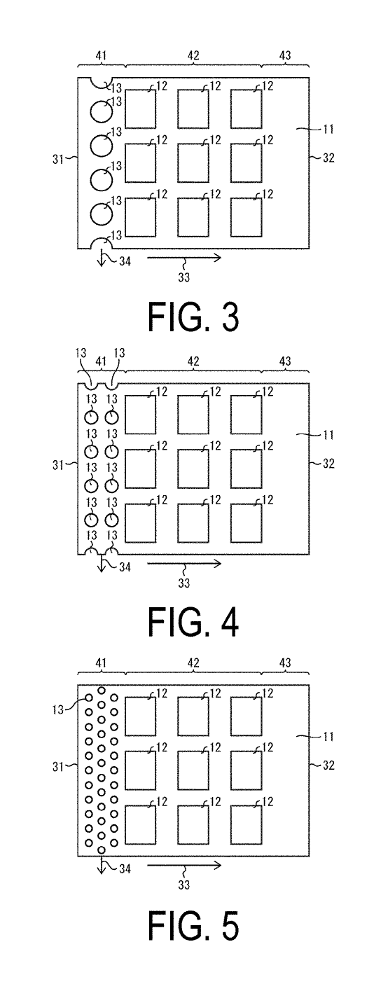

FIG. 3 is a plan view for illustrating an arrangement example of the missing parts 13. FIG. 3 is a view of an intermediate structure in the manufacturing method illustrated in FIG. 2C, which is viewed from a formation surface of the resin film 11. In the example of FIG. 3, the plurality of display elements 12 arranged in a matrix shape are formed on the resin film 11. As illustrated in FIG. 2C and FIG. 3, in the step of forming the missing parts 13, the plurality of missing parts 13 arranged in an array in one row along a direction 34 orthogonal to a peeling direction 33 of the resin film 11 are formed. The plurality of missing parts 13 are arranged in an array away from each other at an equal interval.

Two missing parts 13 among the plurality of missing parts 13 overlap with end portions of the resin film 11, which are parallel to the peeling direction 33. The two missing parts 13 overlapping with the end portions are formed as notches from which parts of the resin film 11 are cut out. Only some parts of the two missing parts 13 overlapping with the end portions are surrounded by the resin film 11, and the two missing parts 13 have the same shape and the same size with each other. In FIG. 3, each of the two missing parts 13 overlapping with the end portions has a semi-circular shape.

The remaining four missing parts 13 among the plurality of missing parts 13 are away from all the end portions of the resin film 11. The four missing parts 13 away from the end portions are formed as cutouts from which parts of the resin film 11 are cut out. The four missing parts 13 away from the end portions are completely surrounded by the resin film 11, and have the same shape and the same size with one another. In FIG. 3, each of the four missing parts 13 away from the end portions has a circular shape.

### Peeling of Resin Layer 11

After the missing parts 13 are formed, the resin film 11 is peeled off from the peeling start position 31 mechanically (FIG. 2D and FIG. 2E). In this step, first, a starting point of peeling is generated by, for example, inserting a sharp blade between a bottom surface of the peeling start position 31 of the resin film 11 and the rigid substrate 21. Subsequently, a physical force is applied in a direction substantially perpendicular to the surface of the resin film 11 at a position at which the starting point of peeling is generated on the resin film 11. With this, a stress parallel to the resin film 11 is applied to the resin film 11.

The missing parts 13 are close to the peeling start position 31 compared to the display elements 12. Thus, the stress applied to the resin film 11 concentrates on the missing parts 13. As a result, the missing parts 13 and the resin film 11 around the missing parts 13 are deformed, and further, a crack is formed in the resin film 11 around the missing parts 13. With this, an excessive stress applied at the time of peeling off the resin film 11 from the rigid substrate 21 is absorbed in the resin film 11 in the vicinity of the missing parts 13. Thus, a strong force is prevented from concentrating on the resin film 11 around the display elements 12. Therefore, without damaging the display elements 12, the resin film 11 can completely be peeled off from the rigid substrate 21 (FIG. 2E).

After the resin film 11 is peeled off, a periphery of each of the display elements 12 on the resin film 11 is cut away. Accordingly, a plurality of display devices 1 are obtained (FIG. 2F). In this manner, manufacturing of the display device 1 is completed.

Before a step of peeling off the resin film 11 is performed, a back surface of the resin film 11 can be irradiated with a laser. With the laser irradiation, it is expected that physical adhesion between the resin film 11 and the rigid substrate 21 can be suppressed. Even when the adhesion is not sufficiently suppressed, and after the laser irradiation, a strong stress is applied to the resin film 11 at the time of peeling off the resin film 11 mechanically, the stress is reduced due to an action of the missing parts 13 formed in the region 41. Therefore, similar to the case where the resin film 11 is peeled off without using laser irradiation, the resin film 11 can be peeled off without damaging the display elements 12.

### Other Arrangement of Missing Parts 13

FIG. 4 is a plan view for illustrating another arrangement example of the missing parts 13. In FIG. 4, in the step of forming the missing parts 13, the plurality of missing parts 13 arranged in two rows are formed. Among the two rows, a plurality of missing parts 13 configuring a first row close to the peeling start position 31 are arranged in an array at an equal interval along the direction 34 orthogonal to the peeling direction 33. Among the two rows, a plurality of missing parts 13 configuring a second row close to the display element 12 are also arranged to be arranged in an array at an equal interval along the direction 34 orthogonal to the peeling direction 33.

In the configuration of FIG. 4, the total number of missing parts 13 arranged in the region 41 is larger than that in the configuration of FIG. 3. Further, the plurality of missing parts 13 are arranged to be scattered in a larger range over the entire region 41. With those, in the configuration of FIG. 4, after the peeling of the resin film 11 is started, a stress focusing on the respective missing parts 13 is increased. As a result, the stress to be applied to the display element 12 is further reduced. Thus, at the time of peeling off the resin film 11, a risk of damaging the display elements 12 can further be suppressed.

FIG. 5 is a plan view for illustrating another arrangement example of the missing parts 13. In FIG. 5, in the step of forming the missing parts 13, the plurality of missing parts 13 arranged in three rows are formed. The plurality of missing parts 13 forming any one row of the three rows are arranged in an array at an equal interval along the direction 34 orthogonal to the peeling direction 33. The plurality of missing parts 13 included in the center row among the three rows are each arranged at positions shifted in the peeling direction 33 from each of the plurality of missing parts 13 included in both the adjacent rows. In the configuration of FIG. 5, six missing parts 13 arranged in a periphery of any one of the missing parts 13 included in the center row are arranged in a regular hexagonal shape. In other words, in the region 41, the plurality of missing parts 13 are arranged in a balanced manner in a plan view.

Note that, in the step of forming the missing parts 13, the plurality of missing parts 13 arranged in a honeycomb shape may be formed. In this case, the plurality of missing parts 13 arranged without a gap therebetween are formed in the region 41.

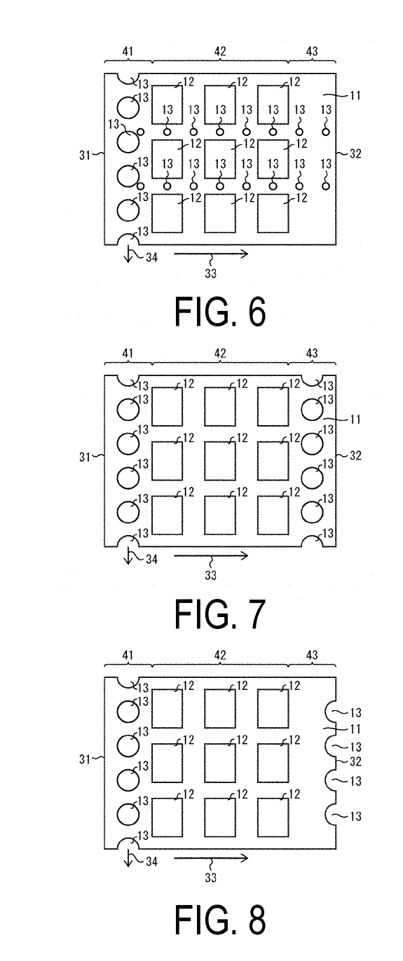

FIG. 6 is a plan view for illustrating another arrangement example of the missing parts 13. At the time of manufacturing the display device 1, in the step of forming the missing parts 13, as illustrated in FIG. 6, the missing parts 13 may be formed also at positions between the different display elements 12 in a region 42 (second region) in which the plurality of display elements 12 are formed on the resin film 11. More specifically, as illustrated in FIG. 6, the plurality of missing parts 13 in the two lines, which are arranged at an equal interval in the peeling direction 33, are formed in the region 41, the region 42, and a region 43. It is not necessarily required to form the missing parts 13 in the region 43. In FIG. 6, each line is formed of eight missing parts 13 in total. One of the eight missing parts 13 forming one line is formed in the region 41, five of them are formed in the region 42, and the remaining two of them are formed in the region 43. Those eight missing parts 13 are smaller than the missing parts 13 in one row formed in the region 41.

Note that, in the step of forming the missing parts 13, some of the plurality of missing parts 13 in the two lines, which are arranged in an array in the peeling direction 33, can be formed at positions between two adjacent missing parts 13 of the plurality of missing parts 13, which are arranged in an array along the direction 34 in the region 41.

Three of the five missing parts 13 arranged in the region 42 are independently formed between the two display elements 12 arranged in an array in the direction 34. In other words, those three missing parts 13 are formed at positions facing the display elements 12 in the direction 34. The remaining two of the five missing parts 13 arranged in the region 42 are not formed between the two display elements 12 arranged in an array in the direction 34. In other words, those two missing parts 13 are formed at positions not facing the display elements 12 in the direction 34.

In the configuration of FIG. 6, the missing parts 13 formed between the different display elements 12 in the region 42 suppress deformation of the resin film 11 in the vicinity of the display elements 12, which may be caused by a shearing stress specific to a resin material configuring the resin film 11. When the resin film 11 is peeled off, a possibility of damaging the display elements 12 can further be suppressed.

FIG. 7 is a plan view for illustrating another arrangement example of the missing parts 13. At the time of manufacturing the display device 1, in the step of forming the missing parts 13, as illustrated in FIG. 7, the missing parts 13 can be formed even in the region 43 (third region) between the display element 12 and a peeling completion position 32 on the resin film 11. In FIG. 7, the plurality of missing parts 13 arrayed in one low along the direction 34 are formed. In the configuration of FIG. 7, the missing parts 13 are formed in the region 43. Thus, a degree of adhesion between the region 43 and the rigid substrate 21 is low. Therefore, after the resin film 11 is completely peeled off to the region 42, the peeling can be performed easily even in the region 43 in the last place.

FIG. 8 is a plan view for illustrating another arrangement example of the missing parts 13. At the time of manufacturing the display device 1, in the step of forming the missing parts 13, as illustrated in FIG. 8, the missing parts 13 can be formed also in the region 43 between the display element 12 and the peeling completion position 32 on the resin film 11. In FIG. 8, the plurality of missing parts 13 arrayed in one low along the direction 34 are formed. Those missing parts 13 overlap with the peeling completion position 32 on the resin film 11, and have a semi-circular shape. Also with this configuration, similarly to the configuration of FIG. 7, the peeling can be performed easily even in the region 43 in the last place.

### Supplement

Aspect 1: A display device manufacturing method, including forming a resin film on a rigid substrate, forming a display element on the resin film, forming a missing part, the missing part is missing a part of the resin film, in a first region between a peeling start position on the resin film and the display element, and peeling the resin film mechanically from the peeling start position after the display element and the missing part are formed.

Aspect 2: The display device manufacturing method according to Aspect 1, in which, in the forming a missing part, a plurality of missing parts arranged in an array along a direction orthogonal to a peeling direction of the resin film are formed in the first region.

Aspect 3: The display device manufacturing method according to Aspect 2, in which, in the forming a missing part, the plurality of missing parts arranged in a plurality of rows are formed in the first region.

Aspect 4: The display device manufacturing method according to any one of Aspects 1 to 3, in which, in the forming a display element, a plurality of display elements arranged away from each other are formed, and in which, in the forming a missing part, the missing part is formed at a position between the different display elements in a second region, the second region is formed with the plurality of display elements on the resin film.

Aspect 5: The display device manufacturing method according to Aspect 4, in which, in the forming a missing part, a plurality of missing parts arranged in an array in a peeling direction of the resin film are formed from the first region to the second region.

Aspect 6: The display device manufacturing method according to Aspect 5, in which, in the forming a missing part, the plurality of missing parts arranged in an array along a direction orthogonal to the peeling direction of the resin film are formed in the first region, and a part of the plurality of missing parts arranged in an array in the peeling direction is formed in the first region at a position between two adjacent missing parts among the plurality of missing parts arranged in an array along the direction orthogonal to the peeling direction.

Aspect 7: The display device manufacturing method according to any one of Aspects 4 to 6, in which, in the forming a missing part, the missing part smaller than the missing part formed in the first region is formed in the second region.

Aspect 8: The display device manufacturing method according to any one of Aspects 1 to 7, in which, in the forming a missing part, the missing part is formed in a third region between a peeling completion position of the resin film and the display element on the resin film.

Aspect 9: The display device manufacturing method according to any one of Aspects 1 to 8, in which the missing part is away from an end portion of the resin film, and has a circular shape.

Aspect 10: The display device manufacturing method according to any one of Aspects 1 to 8, in which the missing part overlaps with an end portion of the resin film, and has a semi-circular shape.

The disclosure is not limited to the above-mentioned embodiments, and various changes can be made within the scope of claims. Embodiments obtained by appropriately combining technical approaches stated in each of the different embodiments also fall within the scope of the technology of the disclosure. Moreover, novel technical features may be formed by combining the technical approaches stated in each of the embodiments.

### REFERENCE SIGNS LIST

1 Display device
11 Resin film
12 Display element
13 Missing part
21 Rigid substrate
31 Peeling start position
32 Peeling completion position
33 Peeling direction
34 Direction
41 Region (first region)
42 Region (second region)
43 Region (third region)

1. A display device manufacturing method, comprising:
forming a resin film on a rigid substrate;
forming a display element on the resin film;
forming a missing part, the missing part is missing a part of the resin film, in a first region between a peeling start position on the resin film and the display element; and
peeling the resin film mechanically from the peeling start position after the display element and the missing part are formed,
wherein, in the forming a display element, a plurality of display elements arranged away from each other are formed, and
in the forming a missing part, the missing part is formed at a position between the different display elements in a second region, the second region is formed with the plurality of display elements on the resin film.

2. The display device manufacturing method according to claim 1,
wherein, in the forming a missing part, a plurality of missing parts arranged in an array along a direction orthogonal to a peeling direction of the resin film are formed in the first region.

3. The display device manufacturing method according to claim 2,
wherein, in the forming a missing part, the plurality of missing parts arranged in a plurality of rows are formed in the first region.

4. (canceled)

5. The display device manufacturing method according to claim 1,
wherein, in the forming a missing part, a plurality of missing parts arranged in an array in a peeling direction of the resin film are formed from the first region to the second region.

6. The display device manufacturing method according to claim 5,
wherein, in the forming a missing part,
the plurality of missing parts arranged in an array along a direction orthogonal to the peeling direction of the resin film are formed in the first region, and
a part of the plurality of missing parts arranged in an array in the peeling direction is formed in the first region at a position between two adjacent missing parts among the plurality of missing parts arranged in an array along the direction orthogonal to the peeling direction.

7. The display device manufacturing method according to claim 1,
wherein, in the forming a missing part, the missing part smaller than the missing part formed in the first region is formed in the second region.

8. The display device manufacturing method according to claim 1,
wherein, in the forming a missing part, the missing part is formed in a third region between a peeling completion position of the resin film and the display element on the resin film.

9. The display device manufacturing method according to claim 1,
wherein the missing part is away from an end portion of the resin film, and has a circular shape.

10. The display device manufacturing method according to claim 1,
wherein the missing part overlaps with an end portion of the resin film, and has a semi-circular shape.

11. A display device manufacturing method, comprising:
forming a resin film on a rigid substrate;
forming a display element on the resin film;
forming a missing part, the missing part is missing a part of the resin film, in a first region between a peeling start position on the resin film and the display element; and
peeling the resin film mechanically from the peeling start position after the display element and the missing part are formed,
wherein the missing part is away from an end portion of the resin film, and has a circular shape.

12. The display device manufacturing method according to claim 11,
wherein, in the forming a missing part, a plurality of missing parts arranged in an array along a direction orthogonal to a peeling direction of the resin film are formed in the first region.

13. The display device manufacturing method according to claim 12,
wherein, in the forming a missing part, the plurality of missing parts arranged in a plurality of rows are formed in the first region.

14. The display device manufacturing method according to claim 11,
wherein, in the forming a missing part, the missing part is formed in a third region between a peeling completion position of the resin film and the display element on the resin film.

15. A display device manufacturing method, comprising:
forming a resin film on a rigid substrate;
forming a display element on the resin film;
forming a missing part, the missing part is missing a part of the resin film, in a first region between a peeling start position on the resin film and the display element; and
peeling the resin film mechanically from the peeling start position after the display element and the missing part are formed,
wherein the missing part overlaps with an end portion of the resin film, and has a semi-circular shape.

16. The display device manufacturing method according to claim 15,
wherein, in the forming a missing part, a plurality of missing parts arranged in an array along a direction orthogonal to a peeling direction of the resin film are formed in the first region.

17. The display device manufacturing method according to claim 16,
wherein, in the forming a missing part, the plurality of missing parts arranged in a plurality of rows are formed in the first region.

18. The display device manufacturing method according to claim 15,
wherein, in the forming a missing part, the missing part is formed in a third region between a peeling completion position of the resin film and the display element on the resin film.
